(19) United States
(12) Patent Application Publication
(10) Pub. No.: US 2009/0166656 A1
(43) Pub. Date: Jul. 2, 2009

(54) LIGHT EMITTING DIODE

(75) Inventors: FANG-XIANG YU, Shenzhen (CN); SHUN-YUAN JAN, Tu-Cheng (TW); CHUNG-YUAN HUANG, Santa Clara, CA (US)

Correspondence Address: PCE INDUSTRY, INC.;ATT. Steven Reiss, 458 E. LAMBERT ROAD, FULLERTON, CA, 92835, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/045,677

(22) Filed: Mar. 10, 2008

(30) Foreign Application Priority Data
Dec. 27, 2007 (CN) 200710186117.3

(51) Int. Cl. H01L 33/00

(52) U.S. Cl. 257/98; 257/E33.067

(57) ABSTRACT

A light emitting diode (LED) (100) includes a base (200), a chip body (300) and an encapsulation portion (400) sealing the chip body (300) in the base (200). The base (200) has a concave depression (220) defined therein. The depression (220) has a bottom wall (222) and a sidewall (224) extending upwardly from the bottom wall (222). The sidewall (224) is arranged in a half-ellipsoidal surface round the bottom wall (222). The chip body (300) is disposed on the bottom wall (222). The encapsulation portion (400) has a bottom portion (440) and a top portion (420). The bottom portion (440) has an outer surface (442) matingly received in the depression (220), and the top portion (420) has a convex, half-ellipsoidal surface (422). The sidewall (224) reflects light generated by the chip body (300) to run through the convex, half-ellipsoidal surface (422).

### BACKGROUND OF THE INVENTION

1. Field of the Invention

The present invention relates to a light emitting diode, and particularly to a light emitting diode, which can be directly used in a lighting equipment without secondary optics.

2. Description of related art

Light emitting diodes (LEDS) are a commonly used light source in applications including lighting, signaling, signage and displays. The LED has several advantages over incandescent and fluorescent lamps, including high efficacy, high brightness, long life, and stable light output. It creates much higher illuminance and space brightness with less electricity consumption.

A related LED is shown in FIG. 6. The related LED includes a base 16, a chip body 13 mounted on the base 16, and an encapsulation 15 sealing the chip body 13. The encapsulation 15 is made of a transparent or translucent epoxy resin. Light is emitted by the conventional LED in a generally upward direction.

When the related LED is used in a lighting equipment, particularly a road lamp, secondary optics 17 have to be added to redirect the light to meet the specific lighting requirements of the road lamp. These optics 17 are called “secondary” to distinguish them from the “primary optics” of the conventional LED itself, such as the encapsulation 15. The design of the secondary optics 17 is called “the secondary optics design. In general, the secondary optics 17 includes lenses, which are usually positioned between the related LED and the desired direction of the light emission.

However, the secondary optics 17 is separately manufactured from the primary optics, i.e. the encapsulation 15 and then assembled together with the primary optics, which leads to a raise of the cost of the lighting equipment. As the lighting industry is a highly price competitive market, device manufacturers are motivated to reduce the bill of materials of a given device, enabling either higher profit or a reduced price to the end user.

What is needed, therefore, is an LED, which has an integral secondary optics and can be directly used in a lighting equipment without a separate secondary optics to meet the specific lighting requirements of the lighting equipment, particularly a road lamp.

### SUMMARY OF THE INVENTION

In accordance with an embodiment of the present invention, a light emitting diode (LED) comprises a base, a chip body and an encapsulation portion sealing the chip body in the base. The base has a concave depression defined therein. The depression has a bottom wall and a sidewall expending upwardly from the bottom wall. The sidewall is arranged in a half-ellipsoidal surface round the bottom wall. The chip body is disposed on the bottom wall. The encapsulation portion has a bottom portion and a top portion formed on the bottom portion. The bottom portion has an outer surface mating with the depression, and the top portion has a convex, half-ellipsoidal surface. Light generated by the chip body has a portion directly emitting through the convex, half-ellipsoidal surface and anther portion reflected by the sidewall to run through the convex, half-ellipsoidal surface. The light is re-directed by convex, half-ellipsoidal surface to radiate out of the LED.

Other advantages and novel features of the present invention will become more apparent from the following detailed description when taken in conjunction with the accompanying drawings, in which:

### BRIEF DESCRIPTION OF THE DRAWINGS

Many aspects of the present LED can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is an isometric view of an LED in accordance with a preferred embodiment of the present invention;

FIG. 2 is a schematic, cross-sectional view of FIG. 1;

FIG. 3 is an exploded view of FIG. 1;

FIG. 4 is an exploded view of an LED in accordance with another preferred embodiment of the present invention;

FIG. 5 is a schematic, cross-sectional view of an LED in accordance with still another preferred embodiment of the present invention; and

FIG. 6 is a schematic, cross-sectional view of a related LED, together with secondary optics.

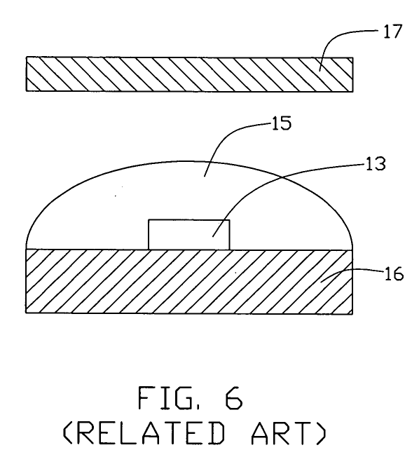

### DETAILED DESCRIPTION OF THE INVENTION

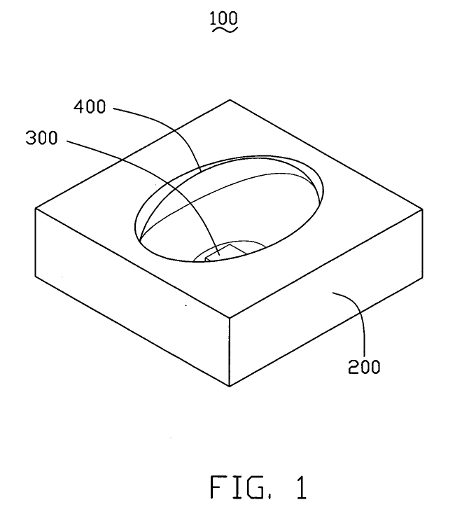

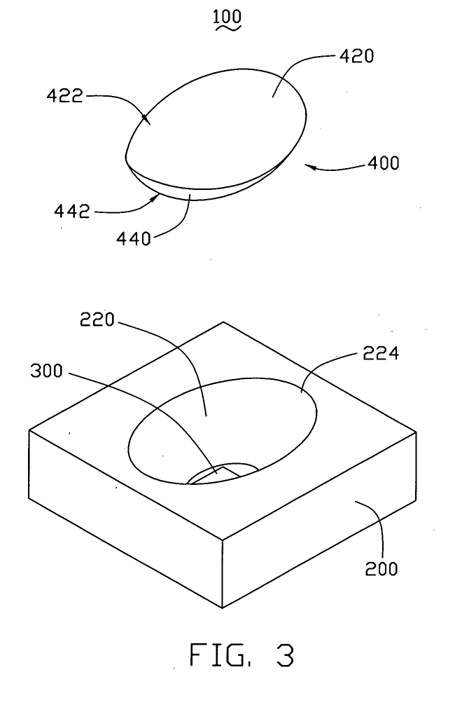

Referring to FIGS. 1-3, a light emitting diode (LED) 100 of a preferred embodiment of the invention is illustrated. The LED 100 comprises a base 200, a chip body 300 and an encapsulation portion 400 sealing the chip body 300 on the base 200.

The base 200 has a rectangular parallelepiped configuration, and has a concave depression 220 defined therein. The depression 220 has a flat bottom wall 222 and a sidewall 224 slantwise expending upwardly from the bottom wall 222. The sidewall 224 is arranged in a half-ellipsoidal surface round the bottom wall 222. In other words, the depression 220 defined by the sidewall 224 and the bottom wall 22 together has an inverted frustum-shaped configuration. Furthermore, the bottom wall 222 and a horizontal cross-section of the depression 220 parallel to the bottom wall 222 each have an elliptic shape. The elliptic cross-section of the depression 220 has a size gradually increasing along a direction from the bottom wall 222 towards a top side of the base 200.

The chip body 300 is mounted on the bottom wall 222 of the depression 220 via a silver paste or other conventional method. The chip body 300 can electrically connect to a printed circuit board via conventional methods.

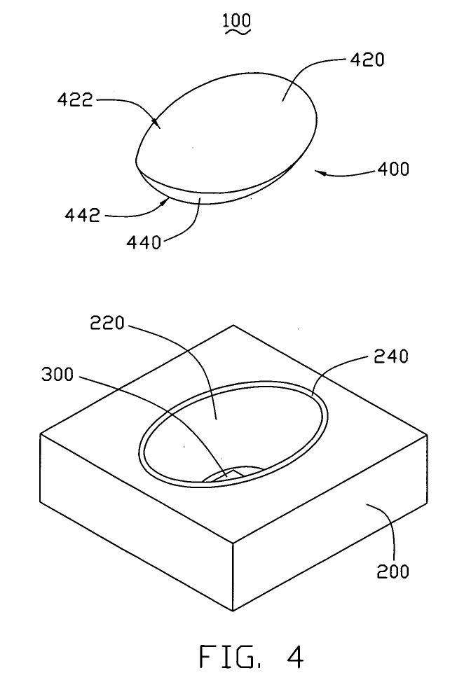

The base 200 is made of metal material such as aluminum; the inner surface of the sidewall 224 is polished so that the sidewall 224 serves as a light reflector to efficiently reflect the light from the chip body 300. However, in another embodiment as shown in FIG. 4, the base 200 is made of a material selected from one of metal material, resin, plastic and so on, and a light reflecting layer 240 is provided on the inner surface of the sidewall 224. The light reflecting layer 240 is configured for reflecting the light from the chip body 300. The material of the light reflecting layer 240 is chosen from a metal such as silver, gold, or aluminum, or an alloy of the metal.

The encapsulation portion 400 serves to redirect the light from the chip body 300 and the light reflector, in addition to protecting the chip body 300 from external physical and/or electrical shock. The encapsulation portion 400 has a shape of an ellipsoid, and can be divided into a top portion 420 and a bottom portion 440.

The bottom portion 440 is located within the depression 220. The bottom portion 440 has an outer surface 442 mates with the inner surface of the depression 220 so that the chip body 300 is sealed in the depression 220 by the encapsulation portion 400.

The top portion 420 is formed on the top side of the bottom portion 440, and is in shape of a half-ellipsoid. The top portion 420 has a convex, half-ellipsoidal surface 422 to control of the direction of the light radiated from the chip body 300 and the light reflector and emitted out of the LED 100.

By the presence of the sidewall 224 of the depression 220 and the convex, half-ellipsoidal surface 422 of the encapsulation portion 400, the light from the chip body 300 can be reflected and redirected to meet the specific lighting requirements of the road lamp, without the necessity of a separate secondary optics assembled over the LED. Furthermore, the LED 100 of the instant invention without the separate secondary optics can achieve the same illuminance and space brightness as the related LED with the separate secondary optics. Therefore, the cost of a lighting equipment with the LED 100 is decreased due to the omission of the separate secondary optics. In addition, the lighting equipment with the LED 100 can have a compact design.

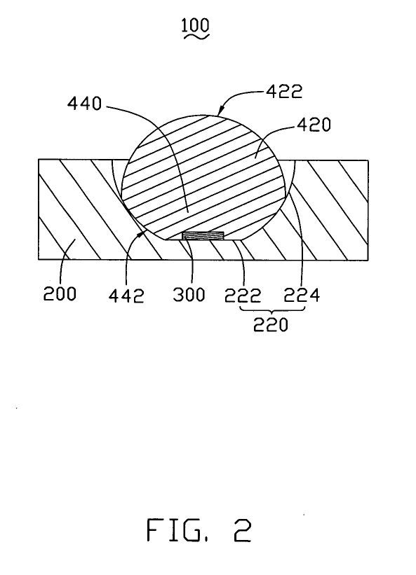

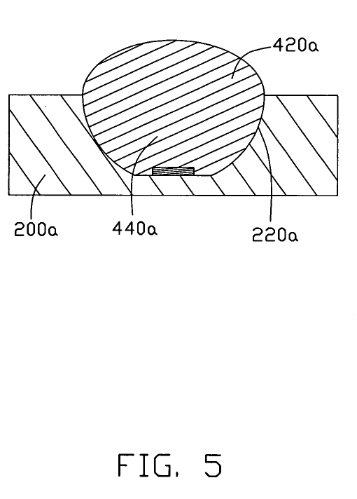

In the embodiment shown in FIG. 2, the bottom portion 440 is immerged into the depression 220 with the sidewall 224 encircling a bottom part of the top portion 420. However, in another embodiment as shown in FIG. 5, a top portion 420a is located above a top side of the base 200a with a bottom portion 440a filling up a depression 220a of the base 200a.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A lighting emitting diode (LED) comprising:
a base with a concave depression defined therein, the depression having a bottom wall and a sidewall extending upwardly and curvedly from the bottom wall, the sidewall being arranged in a half-ellipsoidal surface round the bottom wall, the bottom wall having an elliptic shape, a cross-section of the depression parallel to the bottom wall having an elliptic shape, the elliptic cross-section of the depression having a size gradually increasing along a direction from the bottom wall towards a top side of the base;
a chip body disposed on the bottom wall; and
an encapsulation portion sealing the chip body in the base, the encapsulation portion having a bottom portion and a top portion formed on the bottom portion;
wherein the bottom portion has an outer surface mating with the depression, and the top portion has a convex, half-ellipsoidal surface; and
wherein light generated by the chip body is reflected by the sidewall and then through the convex, half-ellipsoidal surface.

2. The LED as described in claim 1, wherein the top portion has a shape of half-ellipsoid.

3. The LED as described in claim 1, wherein the bottom portion is immerged into the depression with the sidewall encircling a bottom part of the top portion.

4. The LED as described in claim 1, wherein the top portion is located above the top side of the base with the bottom portion filling up the depression.

5. The LED as described in claim 1, wherein the sidewall is polished so that the sidewall can reflect the light from the chip body.

6. The LED as described in claim 5, wherein the base is made of metal material.

7. The LED as described in claim 1, wherein a light reflecting layer is provided on the sidewall so that the sidewall can reflect the light from the chip body.

8. The LED as described in claim 7, wherein the base is made of a material selected from one of metal material, resin, plastic.

9. The LED as described in claim 1, wherein the chip body is mounted on the bottom wall.

10. The LED as described in claim 9, wherein the bottom wall is flat.

11. (canceled)

12. A lighting emitting diode (LED) comprising:
a base having a concave depression defined therein and recessed downwards from a top side toward a bottom side of the base, the depression having an inverted frustum-shaped configuration, and a sidewall around the concave depression, the sidewall being curved upwardly and outwardly from a bottom of the depression along a bottom-to-top direction of the base, a cross-section of the depression perpendicular to a central axis of the depression through the top and bottom sides of the base having an elliptic shape;
a chip body disposed in the depression for generating light; and
an encapsulation portion having a bottom portion disposed in the depression to seal the chip body in the base and a top portion formed on the bottom portion, the top portion having a convex, half-ellipsoidal surface;
wherein a portion of the light generated by the chip body is reflected by the sidewall of the base and then through the top portion of the encapsulation portion and another portion of the light generated by the chip body runs directly through the top portion of the encapsulation portion, the convex, half-ellipsoidal surface of the top portion redirecting the light to radiate out of the LED.

13. The LED as described in claim 12, wherein the depression includes an elliptical bottom wall supporting the chip body thereon.

14. The LED as described in claim 13, wherein the elliptic cross-section of the depression perpendicular to the central axis of the depression through the top and bottom sides of the base is parallel to the bottom wall.

15. The LED as described in claim 14, wherein a light reflecting layer is provided on the sidewall so that the sidewall can reflect the portion of the light generated by the chip body.

16. The LED as described in claim 14, wherein the sidewall is polished so that the sidewall can reflect the portion of the light generated by the chip body.

17. The LED as described in claim 14, wherein the bottom portion is immerged into the depression with the sidewall encircling a bottom part of the top portion.

18. The LED as described in claim 14, wherein the top portion is located above the top side of the base with the bottom portion filling up the depression.

19. An LED comprising:
a base having a sidewall and a bottom wall together defining a depression in the base, the sidewall extending upwardly and curvedly from a periphery of the bottom wall, the bottom wall having an elliptic shape, a cross-section of the depression parallel to the bottom wall having an elliptic shape;
a light-generating chip body received in the depression and mounted on the bottom wall of the base; and
a capsulation portion having at least a part received in the depression and enclosing the chip body therein;
wherein the sidewall reflects a portion of light generated by the chip body to run through the capsulation portion and the capsulation portion redirects another portion of the light directly from the chip body and the portion of the light from the sidewall to radiate out of the LED.

20. The LED as described in claim 19, wherein the encapsulation portion has a convex, ellipsoidal surface over the chip body, and the light generated by the LED runs through the convex-ellipsoidal surface to radiate out of the LED.
